(19) United States
(12) Patent Application Publication
(10) Pub. No.: US 2025/0196714 A1
(43) Pub. Date: Jun. 19, 2025

(54) APPARATUS FOR PREDICTING SOH OF BATTERY AND METHOD THEREOF

(71) Applicants: Hyundai Motor Company, Seoul (KR); Kia Cprporation, Seoul (KR)

(72) Inventor: Yoon Sung CHOI, Hwaseong-Si (KR)

(73) Assignees: Hundai Motor Company, Seoul (KR); Kia Corporation, Seoul (KR)

(21) Appl. No.: 18/676,010

(22) Filed: May 28, 2024

(30) Foreign Application Priority Data
Dec. 19, 2023 (KR) 10-2023-0186229

(51) Int. Cl. B60L 58/16

(52) U.S. Cl. CPC B60L 58/16; B60L 2240/12; B60L 2240/545; B60L 2240/547; B60L 2240/549; B60L 2260/50

(57) ABSTRACT

In an apparatus for predicting a state of health (SOH) of a battery and a method thereof, the apparatus includes a training dataset including battery information, driving information, and an SOH of a probe vehicle, trains an artificial intelligence (AI) model by use of the training dataset, and predicts the SOH of the battery corresponding to the battery information and driving information of the target vehicle based on the AI model, predicting the SOH of the battery provided in the target vehicle with predetermined accuracy.

### CROSS-REFERENCE TO RELATED APPLICATION

The present application claims priority to Korean Patent Application No. 10-2023-0186229, filed on Dec. 19, 2023, the entire contents of which is incorporated herein for all purposes by this reference.

### BACKGROUND OF THE PRESENT DISCLOSURE

### Field of the Present Disclosure

The present disclosure relates to a technology for predicting the state of health (SOH) of a battery based on an artificial neural network model.

### Description of Related Art

In general, an artificial neural network (ANN), which is a field of artificial intelligence, is an algorithm for allowing a machine to learn made by simulating a human neural structure. Recently, it has been applied to image recognition, speech recognition, natural language processing, and the like, and has shown excellent effects. An artificial neural network includes an input layer that receives an input, a hidden layer that actually learns, and an output layer that returns the result of an operation. The artificial neural network including the plurality of hidden layers is called a deep neural network (DNN), which is also a kind of the artificial neural network.

An artificial neural network allows a computer to learn by itself based on data. When trying to solve a problem using an artificial neural network, it is necessary to prepare a suitable artificial neural network model and data to be analyzed. An artificial neural network model to solve a problem is trained based on data. Before training the model, it is necessary to properly process the data first. This is because the input data and the output data required by the artificial neural network model are standardized. Therefore, a process of preprocessing the obtained raw data to suit the requested input data is required. After the preprocessing is completed, the processed data are required to be divided into two types. That is, the data should be divided into a train dataset and a validation dataset. The train dataset is used to train the model, and the validation dataset is used to verify the performance of the model.

There are various reasons for validating an artificial neural network model. An artificial neural network developer tunes the model by modifying the hyper parameters of a model based on the verification result of the model. Furthermore, the model verification is performed to select a suitable model from various models. The reason why the model verification is necessary is explained in more detail as follows.

The first is to predict accuracy. As a result, the purpose of artificial neural networks is to achieve good performance on out-of-sample data not used for training. Therefore, after generating the model, it is essential to check how well the model will perform on out-of-sample data. However, because the model should not be verified using the train dataset, the accuracy of the model should be measured using the validation dataset separated from the train dataset.

The second is to increase the performance of the model by tuning the model. For example, it is possible to prevent overfitting. Overfitting means that the model is over-trained on the train dataset. For example, when the training accuracy is high but the validation accuracy is low, the occurrence of overfitting may be suspected. Furthermore, it may be understood in more detail through training loss and validation loss. When overfitting occurs, it is necessary to prevent overfitting to increase the validation accuracy. It is possible to prevent overfitting by use of a scheme such as regularization or dropout.

Meanwhile, a conventional technology for predicting SOH of a battery predicts SOHc based on the capacity of the battery, predicts SOHr based on the resistance of the battery, and predicts the final SOH based on the SOHc and the SOHr.

Such a conventional technology has low prediction accuracy because it predicts SOH using only battery information.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus for predicting a state of health (SOH) of a battery and a method thereof configured for predicting the SOH of the battery provided in a target vehicle with high accuracy by including a training dataset including battery information, driving information, and an SOH of a probe vehicle, training an artificial intelligence (AI) model by use of the training dataset, and predicting the SOH of the battery corresponding to the battery information and driving information of the target vehicle based on the AI model.

Another aspect of the present disclosure provides an apparatus for predicting a SOH of a battery and a method thereof configured for predicting the SOH of the battery provided in a target vehicle with high accuracy by including an AI model that learns the SOH of the battery corresponding to the battery information and driving information of a probe vehicle, and predicting the SOH of the battery corresponding to the battery information and driving information of the target vehicle based on the AI model.

Yet another aspect of the present disclosure provides an apparatus for predicting a SOH of a battery and a method thereof configured for predicting the SOH of the battery provided in a target vehicle with high accuracy by including a training dataset including battery information, driving information, and an SOH of a probe vehicle, training an AI model by use of the training dataset, predicting a first SOH of the battery corresponding to the battery information and driving information of the target vehicle based on the AI model, obtaining a second SOH from a battery management system (BMS) provided in the target vehicle, and correcting the first SOH by use of the second SOH.

Yet another aspect of the present disclosure provides an apparatus for predicting a SOH of a battery and a method thereof configured for predicting the SOH of the battery provided in a target vehicle with high accuracy by including an AI model that learns the SOH of the battery corresponding to the battery information and driving information of a probe vehicle, predicting a first SOH of the battery corresponding to the battery information and driving information of the target vehicle based on the AI model, obtaining a second SOH from a battery management system (BMS) provided in the target vehicle, and correcting the first SOH by use of the second SOH.

The technical problems to be solved by the present disclosure are not limited to the aforementioned problems, and any other technical problems not mentioned herein will be clearly understood from the following description by those skilled in the art to which the present disclosure pertains. Also, it may be easily understood that the objects and advantages of the present disclosure may be realized by the units and combinations thereof recited in the claims.

According to an aspect of the present disclosure, an apparatus for predicting a state of health (SOH) of a battery includes storage that stores a SOH prediction model, and a controller that predicts a first SOH of the battery provided in a target vehicle based on the SOH prediction model, wherein the controller may be configured to predict the first SOH by use of at least one of a speed and an accumulated mileage of the target vehicle, and a voltage, a current, a temperature, and a number of charging times of the battery in the target vehicle.

According to an exemplary embodiment of the present disclosure, the controller may train the SOH prediction model by use of a training dataset including battery information, driving information, and an SOH of a battery in a probe vehicle.

According to an exemplary embodiment of the present disclosure, the battery information may include at least one of a voltage, a current, a temperature, a number of fast charging, a number of slow charging, or a combination thereof in a battery of the probe vehicle.

According to an exemplary embodiment of the present disclosure, the driving information may include at least one of a vehicle speed, an accumulated mileage, a driving time, or a combination thereof.

According to an exemplary embodiment of the present disclosure, the controller may obtain a second SOH of the battery provided in the target vehicle from a battery management system (BMS) through a vehicle network, and correct the first SOH by use of the second SOH.

According to an exemplary embodiment of the present disclosure, the controller may obtain the second SOH of the battery provided in the target vehicle from the BMS when the first SOH of the battery provided in the target vehicle is out of a threshold range.

According to an exemplary embodiment of the present disclosure, the controller may be configured to determine reliability for the first SOH based on a degree to which the first SOH of the battery provided in the target vehicle deviates from a threshold range, and obtain the second SOH of the battery provided in the target vehicle from the BMS when the reliability does not exceed a threshold.

According to an exemplary embodiment of the present disclosure, the controller may be configured to determine a reflection rate of the second SOH based on the reliability when correcting the first SOH by use of the second SOH.

According to another aspect of the present disclosure, a method of predicting a state of health (SOH) of a battery includes storing, by a storage, a SOH prediction model, and predicting, by a controller, a first SOH of the battery provided in a target vehicle based on the SOH prediction model, wherein the predicting of the first SOH includes predicting, by the controller, the first SOH by use of at least one of a speed and an accumulated mileage of the target vehicle, and a voltage, a current, a temperature, and a number of charging times of the battery in the target vehicle.

According to an exemplary embodiment of the present disclosure, the storing of the SOH prediction model may further include training, by the controller, the SOH prediction model by use of a training dataset including battery information, driving information, and an SOH of a battery in a probe vehicle.

According to an exemplary embodiment of the present disclosure, the battery information may include at least one of a voltage, a current, a temperature, a number of fast charging, a number of slow charging, or a combination thereof in a battery of the probe vehicle.

According to an exemplary embodiment of the present disclosure, the driving information may include at least one of a vehicle speed, an accumulated mileage, a driving time, or a combination thereof.

According to an exemplary embodiment of the present disclosure, the predicting of the first SOH may further include obtaining, by the controller, a second SOH of the battery provided in the target vehicle from a battery management system (BMS) through a vehicle network, and correcting, by the controller, the first SOH by use of the second SOH.

According to an exemplary embodiment of the present disclosure, the obtaining of the second SOH may include obtaining, by the controller, the second SOH of the battery provided in the target vehicle from the BMS when the first SOH of the battery provided in the target vehicle is outs of a threshold range.

According to an exemplary embodiment of the present disclosure, the obtaining of the second SOH may include determining, by the controller, reliability for the first SOH based on a degree to which the first SOH of the battery provided in the target vehicle deviates from a threshold range, and obtaining, by the controller, the second SOH of the battery provided in the target vehicle from the BMS when the reliability does not exceed a threshold.

According to an exemplary embodiment of the present disclosure, the correcting of the first SOH may further include determining, by the controller, a reflection rate of the second SOH based on the determined reliability.

According to an aspect of the present disclosure, a system for predicting a state of health (SOH) of a battery includes server that trains a SOH prediction model using a training dataset including battery information, driving information, and a SOH of a probe vehicle; and a SOH prediction apparatus that predicts a first SOH of the battery provided in a target vehicle based on the SOH prediction model, wherein the SOH prediction apparatus is configured to predict the first SOH by use of at least one of a speed and an accumulated mileage of the target vehicle, and a voltage, a current, a temperature, and a number of charging times of the battery in the target vehicle.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION

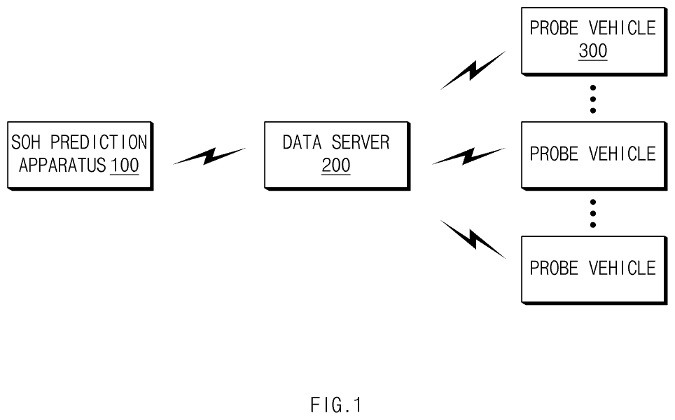

FIG. 1 is a diagram illustrating a system for predicting a SOH of a battery according to an exemplary embodiment of the present disclosure;

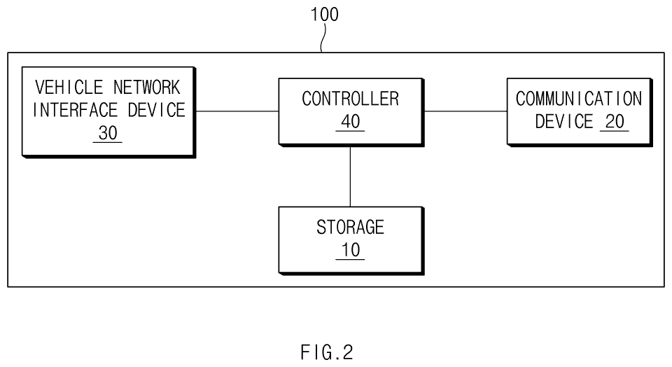

FIG. 2 is a block diagram illustrating a configuration of a battery SOH prediction apparatus according to an exemplary embodiment of the present disclosure;

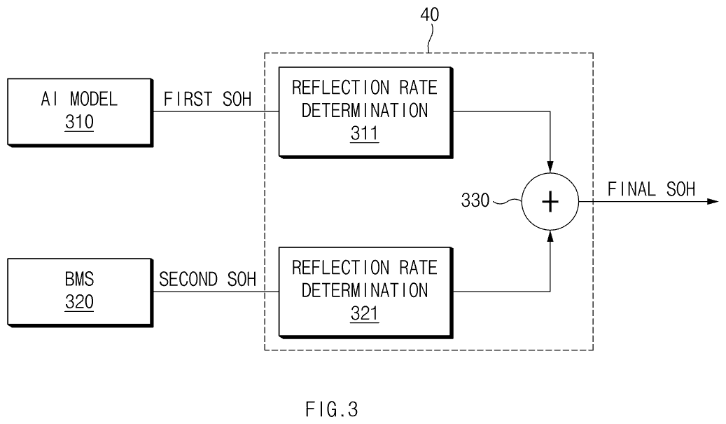

FIG. 3 is a block diagram illustrating a process in which a controller provided in an apparatus for predicting a SOH of a battery according to an exemplary embodiment of the present disclosure is configured to determine a final SOH by use of a first SOH and a second SOH;

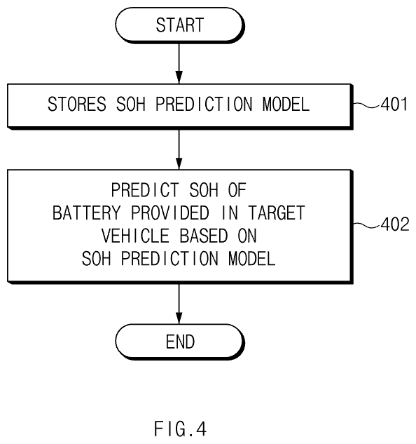

FIG. 4 is a flowchart illustrating a method of predicting a SOH of a battery according to an exemplary embodiment of the present disclosure; and

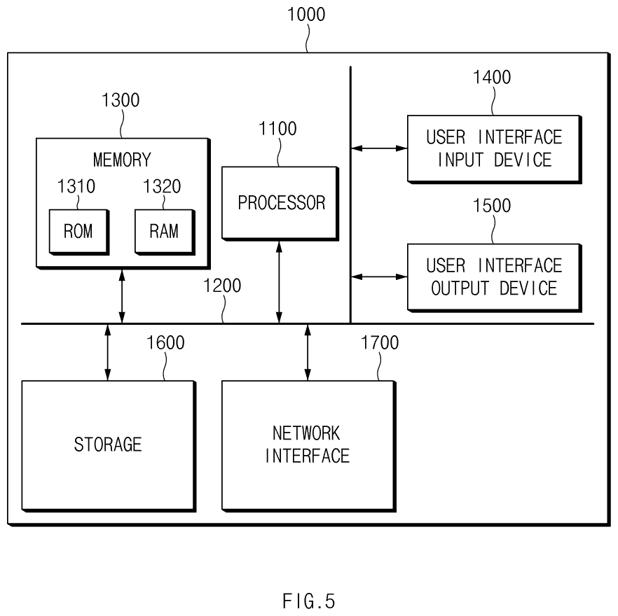

FIG. 5 is a block diagram illustrating a computing system for executing a method of predicting a SOH of a battery according to various exemplary embodiments of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the exemplary drawings. In adding the reference numerals to the components of each drawing, it should be noted that the identical or equivalent component is designated by the identical numeral even when they are displayed on other drawings. Furthermore, in describing the exemplary embodiment of the present disclosure, a detailed description of the related known configuration or function will be omitted when it is determined that it interferes with the understanding of the exemplary embodiment of the present disclosure.

Furthermore, terms, such as first, second, A, B, (a), (b) or the like may be used herein when describing components of the present disclosure. The terms are provided only to distinguish the elements from other elements, and the essences, sequences, orders, and numbers of the elements are not limited by the terms. Furthermore, unless defined otherwise, all terms used herein, including technical or scientific terms, include the same meanings as those generally understood by those skilled in the art to which the present disclosure pertains. The terms defined in the generally used dictionaries should be construed as having the meanings that coincide with the meanings of the contexts of the related technologies, and should not be construed as ideal or excessively formal meanings unless clearly defined in the specification of the present disclosure.

FIG. 1 is a diagram illustrating a system for predicting a SOH of a battery according to an exemplary embodiment of the present disclosure.

As shown in FIG. 1, a system for predicting a SOH of a battery according to an exemplary embodiment of the present disclosure may include a SOH prediction apparatus 100, a data server 200, and at least one probe vehicle 300.

In various exemplary embodiments of the present disclosure, the SOH prediction apparatus 100 may be provided in a target vehicle, receive a training dataset including battery information, driving information, and an SOH of the probe vehicle 300, train an AI model by use of the training dataset, and predict an SOH of a battery (i.e., a battery provided in the target vehicle) corresponding to battery information and driving information of a target vehicle based on the AI model.

In various exemplary embodiments of the present disclosure, the SOH prediction apparatus 100 may receive a trained AI model from the data server 200, and predict the SOH of the battery corresponding to the battery information and the driving information of the target vehicle based on the AI model. In the instant case, the data server 200 may train an AI model by use of the training dataset including the battery information, the driving information, and the SOH of the probe vehicle 300.

In various exemplary embodiments of the present disclosure, the SOH prediction apparatus 100 may receive a training dataset including battery information, driving information, and an SOH of the probe vehicle 300 from the data server 200, train an AI model by use of the training dataset, predict a first SOH of a battery (i.e., a battery provided in the target vehicle) corresponding to the battery information and the driving information of the target vehicle based on the AI model, obtain a second SOH from a BMS provided in the target vehicle, and correcting the first SOH by use of the second SOH.

In various exemplary embodiments of the present disclosure, the SOH prediction apparatus 100 may receive a trained AI model from the data server 200, predict a first SOH of the battery corresponding to the battery information and the driving information of the target vehicle based on the AI model, obtain a second SOH from a BMS provided in the target vehicle, and correcting the first SOH by use of the second SOH.

In each of the above embodiments, the probe vehicle and the target vehicle include the same specifications, and the battery provided in the probe vehicle and the battery provided in the target vehicle include the same specifications.

The data server 200 may be configured to generate a training dataset including battery information, driving information, and a SOH of the probe vehicle 300, and may train an AI model by use of the training dataset.

The probe vehicle 300 may periodically transmit battery information and driving information to the data server 200.

FIG. 2 is a block diagram illustrating a configuration of a battery SOH prediction apparatus according to an exemplary embodiment of the present disclosure.

As shown in FIG. 2, the battery SOH prediction apparatus 100 according to an exemplary embodiment of the present disclosure may include storage 10, a communication device 20, a vehicle network interface device 30, and a controller 40. In the instant case, depending on a scheme of implementing the battery SOH prediction apparatus 100 according to an exemplary embodiment of the present disclosure, components may be combined with each other to be implemented as one, or some components may be omitted.

Regarding each component, first, the storage 10 may store a training dataset including battery information, driving information, and a SOH of the probe vehicle 300. In the instant case, the driving information of the probe vehicle 300 may include a vehicle speed and a cumulative mileage, and the battery information of the probe vehicle 300 may include a voltage, a current, a temperature, a number of charging times (e.g., a number of fast charging times, a number of slow charging times, and the like), and the like of the battery.

In addition, the storage 10 may store various logic, algorithms and programs required in the processes of training an AI model by use of the training dataset, and predicting an SOH of a battery (i.e., a battery provided in a target vehicle) corresponding to battery information and driving information of a target vehicle based on the AI model.

In addition, the storage 10 may store various logic, algorithms and programs required in the processes of training an AI model by use of the training dataset, and predicting a first SOH of a battery (i.e., a battery provided in a target vehicle) corresponding to battery information and driving information of a target vehicle based on the AI model, obtaining a second SOH from a BMS provided in the target vehicle, and correcting the first SOH by use of the second SOH.

Meanwhile, the storage 10 may store a trained AI model (i.e., a SOH prediction model of a battery) in which learning is completed.

The communication device 20, which is a module that provides a communication interface with the data server 200, may receive a training dataset including battery information, driving information, and a SOH of the probe vehicle 300 from the data server 200.

Furthermore, the communication device 20 may receive a trained AI model from the data server 200.

The communication device 20 may include at least one of a mobile communication module, a wireless Internet module, and a short-range communication module.

The mobile communication module may communicate with the data server 200 through a mobile communication network constructed according to a technical standard or communication scheme for mobile communication (e.g., Global System for Mobile communication (GSM), Code Division Multi Access (CDMA), code division multi access 2000 (CDMA2000), enhanced voice-data optimized or enhanced voice-data only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTEA), and the like).

The wireless Internet module, which is a module for wireless Internet access, may communicate with the data server 200 through wireless LAN (WLAN), wireless-fidelity (Wi-Fi), Wi-Fi direct, Digital Living Network Alliance (DLNA), Wireless Broadband (WiBro), Worldwide Interoperability for Microwave Access (WiMAX), High Speed Downlink Packet Access (HSDPA), High Speed Uplink Packet Access (HSUPA), Long Term Evolution (LTE), Long Term Evolution-Advanced (LTE-A), and the like.

The short-range communication module may support short-range communication with the data server 200 by use of at least one of Bluetooth™, radio frequency identification (RFID), infrared data association (IrDA), ultra wideband (UWB), ZigBee, Near Field Communication (NFC), and wireless universal serial bus (USB) technology.

The vehicle network interface device 30, which is a module that provides a communication interface with a vehicle network, may periodically receive battery information and driving information from the vehicle network. Furthermore, the vehicle network interface device 30 may receive the SOH of the battery determined by the BMS. In the instant case, the vehicle network may include a Controller Area Network (CAN), a controller area network with flexible data-rate (CAN FD), a Local Interconnect Network (LIN), FlexRay, Media Oriented Systems Transport (MOST), an Ethernet, and the like.

The controller 40 may perform overall control such that each component performs function thereof. The controller 40 may be implemented in a form of hardware or software, or may be implemented in a combination of hardware and software. The controller 40 may be implemented as a microprocessor, but is not limited thereto.

The controller 40 may train an AI model by use of the training dataset stored in the storage 10, and predict a SOH of a battery corresponding to battery information and driving information of a target vehicle based on the AI model. In the instant case, the controller 40 may input the battery information and the driving information of the target vehicle obtained from a vehicle network through the vehicle network interface device 30 into the AI model to predict the SOH of the battery corresponding to the battery information and the driving information of the target vehicle.

In the instant case, the driving information of the target vehicle may include a vehicle speed and a cumulative mileage, and the battery information of the target vehicle may include a voltage, a current, a temperature, a number of charging times (e.g., a number of fast charging times, a number of slow charging times, and the like), and the like of the battery.

For reference, a battery pack includes a preset number of groups in which a plurality of battery cells are connected in parallel to each other to increase current capacity, and includes a structure in which the groups are connected in series to each other to output a rated voltage. In the instant case, the battery cell includes a cathode current collector, an anode current collector, a separator, an active material, an electrolyte, and the like, and is configured for being repeatedly charged and discharged through electrochemical reactions between components. To protect the plurality of battery cells from external shocks such as heat, vibration, and the like, a battery module may be formed by combining the plurality of battery cells into one. To systematically manage a plurality of battery modules, a battery pack (i.e., a battery system) may be formed by use of the plurality of battery modules, a battery management system (BMS), and a cooling device.

Accordingly, the battery information of the vehicle may be one of battery cell information, battery module information, and battery pack information. In detail, the voltage, current, and temperature of a battery of a vehicle may include the voltage, current, and temperature of one of a battery cell, a battery module, and a battery pack.

The controller 40 may train an AI model by use of the training dataset stored in the storage 10, predict a first SOH of a battery corresponding to battery information and driving information of a target vehicle based on the AI model, obtain a second SOH from a BMS provided in the target vehicle, and correcting the first SOH by use of the second SOH

In the instant case, it may be preferable that the controller 40 obtains the second SOH from the BMS through the vehicle network when the first SOH is out of a threshold range, and corrects the first SOH by use of the second SOH. In the instant case, when the first SOH does not exceed the threshold range, the controller 40 may be configured to determine the first SOH as the final SOH of the battery provided in the target vehicle.

Furthermore, the controller may be configured to determine reliability for the first SOH based on a degree to which the first SOH deviates from the threshold range, and obtain the second SOH from the BMS through the vehicle network when the reliability does not exceed a threshold (e.g., 95%).

As an exemplary embodiment of the present disclosure, when the first SOH predicted by the AI model is 85% and the preset threshold range is 79% to 80%, the controller 40 may be configured to determine the reliability for the first SOH as 94.1% (≈8000/85). For reference, the threshold range may be determined in advance by considering the driving time of the target vehicle, the amount of battery usage (Ah or kWh), and the number of charging times.

As an exemplary embodiment of the present disclosure, when the first SOH predicted by the AI model is 90% and the preset threshold range is 79% to 80%, the controller 40 may be configured to determine the reliability for the first SOH as 88.8% (≈8000/90).

As yet another example, when the first SOH predicted by the AI model is 75% and the preset threshold range is 79% to 80%, the controller 40 may be configured to determine the reliability for the first SOH as 94.9% (≈7500/79).

As yet another example, when the first SOH predicted by the AI model is 65% and the preset threshold range is 79% to 80%, the controller 40 may be configured to determine the reliability for the first SOH as 82.2% (≈6500/79).

Meanwhile, when the reliability of the first SOH does not exceed, for example, 95%, the controller 40 may obtain the second SOH from the BMS through the vehicle network. The controller 40 may be configured to determine the reflection rate of the second SOH corresponding to the reliability of the first SOH based on, for example, following Table 1.

TABLE 1

| Reliability of first SOH | Reflection rate of second SOH |
|---|---|
| 90% to 95% | 30% |
| 85% to 90% | 50% |
| 85% or less | 100% |

In Table 1, when the reliability of the first SOH is 94%, the final SOH may be determined by reflecting 70% of the first SOH and 30% of the second SOH. When the reliability of the first SOH is 89%, the final SOH may be determined by reflecting 50% of the first SOH and 50% of the second SOH. When the reliability of the first SOH is 85% or less, the first SOH may not be reflected at all and the second SOH may be determined as the final SOH.

For example, when the first SOH is 90 and the second SOH is 70, the reliability of the first SOH is 88.8, so that the first SOH is reflected by 50% and the second SOH is reflected by 50% to determine the final SOH. That is, the controller 40 may be configured to determine the final SOH as 80 (=90/2+70/2).

FIG. 3 is a block diagram illustrating a process in which a controller provided in an apparatus for predicting a SOH of a battery according to an exemplary embodiment of the present disclosure is configured to determine a final SOH by use of a first SOH and a second SOH.

As shown in FIG. 3, an AI model 301 predicts the first SOH of the battery provided in the target vehicle, and a BMS 320 predicts the second SOH of the battery provided in the target vehicle.

Accordingly, the controller 40 is configured to determine the reliability of the first SOH and is configured to determine the reflection rate of the first SOH based on the reliability of the first SOH in 311. Furthermore, the controller 40 is configured to determine the reflection rate of the second SOH in 321.

Accordingly, the controller 40 may be configured to determine the final SOH based on the reflection rate of the first SOH and the reflection rate of the second SOH in 330.

FIG. 4 is a flowchart illustrating a method of predicting a SOH of a battery according to an exemplary embodiment of the present disclosure.

First, the storage 10 stores a SOH prediction model in 401.

Accordingly, the controller 40 predicts the first SOH of the battery provided in the target vehicle based on the SOH prediction model in 402. In the instant case, the SOH prediction model is a model which is trained based on a training dataset including the battery information, driving information, and SOH of the probe vehicle. In the instant case, the controller 40 may be configured to predict the first SOH by use of at least one of the speed and accumulated mileage of the target vehicle, and the voltage, current, temperature, and number of charging times of the battery.

Further, the controller 40 may control the target vehicle to alert the user when the first SOH is below a threshold. For example, the controller 40 may transmit a warning signal to a cluster within the target vehicle through the vehicle network.

FIG. 5 is a block diagram illustrating a computing system for executing a method of predicting a SOH of a battery according to various exemplary embodiments of the present disclosure.

Referring to FIG. 5, a method of predicting a SOH of a battery according to an exemplary embodiment of the present disclosure described above may be implemented through a computing system 1000. The computing system 1000 may include at least one processor 1100, a memory 1300, a user interface input device 1400, a user interface output device 1500, storage 1600, and a network interface 1700 connected through a system bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a Read-Only Memory (ROM) 1310 and a Random Access Memory (RAM) 1320.

Accordingly, the processes of the method or algorithm described in relation to the exemplary embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, solid state drive (SSD), a detachable disk, or a CD-ROM. The exemplary storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor 1100 and the storage medium may reside in the user terminal as an individual component.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for predicting a state of health (SOH) of a battery, the apparatus comprising:
a storage configured to store a SOH prediction model; and
a controller operatively connected to the storage and configured to predict a first SOH of the battery provided in a target vehicle based on the SOH prediction model,
wherein the controller is further configured to predict the first SOH by use of at least one of a speed and an accumulated mileage of the target vehicle, and a voltage, a current, a temperature, and a number of charging times of the battery in the target vehicle.

2. The apparatus of claim 1, wherein the controller is further configured to train the SOH prediction model by use of a training dataset including battery information of a battery in a probe vehicle, driving information of the probe vehicle, and an SOH of the battery in the probe vehicle.

3. The apparatus of claim 2, wherein the battery information includes at least one of a voltage, a current, a temperature, a number of fast charging, a number of slow charging, or a combination thereof in the battery of the probe vehicle.

4. The apparatus of claim 2, wherein the driving information includes at least one of a vehicle speed, an accumulated mileage, a driving time, or a combination thereof in the probe vehicle.

5. The apparatus of claim 1, wherein the controller is further configured to obtain a second SOH of the battery provided in the target vehicle from a battery management system (BMS) through a vehicle network, and correct the first SOH by use of the second SOH.

6. The apparatus of claim 5, wherein the controller is further configured to obtain the second SOH of the battery provided in the target vehicle from the BMS in response that the first SOH of the battery provided in the target vehicle is out of a threshold range.

7. The apparatus of claim 5, wherein the controller is further configured to determine reliability for the first SOH based on a degree to which the first SOH of the battery provided in the target vehicle deviates from a threshold range, and obtain the second SOH of the battery provided in the target vehicle from the BMS in response that the reliability does not exceed a threshold.

8. The apparatus of claim 7, wherein the controller is further configured to determine a reflection rate of the second SOH based on the reliability in correcting the first SOH by use of the second SOH.

9. A method of predicting a state of health (SOH) of a battery, the method comprising:
storing, by a storage, a SOH prediction model; and
predicting, by a controller operatively connected to the storage, a first SOH of the battery provided in a target vehicle based on the SOH prediction model,
wherein the predicting of the first SOH includes predicting, by the controller, the first SOH by use of at least one of a speed and an accumulated mileage of the target vehicle, and a voltage, a current, a temperature, and a number of charging times of the battery in the target vehicle.

10. The method of claim 9, wherein the storing of the SOH prediction model further includes training, by the controller, the SOH prediction model by use of a training dataset including battery information of a battery in a probe vehicle, driving information of the probe vehicle, and an SOH of the battery in the probe vehicle.

11. The method of claim 10, wherein the battery information includes at least one of a voltage, a current, a temperature, a number of fast charging, a number of slow charging, or a combination thereof in the battery of the probe vehicle.

12. The method of claim 10, wherein the driving information includes at least one of a vehicle speed, an accumulated mileage, a driving time, or a combination thereof in the probe vehicle.

13. The method of claim 9, wherein the predicting of the first SOH further includes:
obtaining, by the controller, a second SOH of the battery provided in the target vehicle from a battery management system (BMS) through a vehicle network; and
correcting, by the controller, the first SOH by use of the second SOH.

14. The method of claim 13, wherein the obtaining of the second SOH includes obtaining, by the controller, the second SOH of the battery provided in the target vehicle from the BMS in response that the first SOH of the battery provided in the target vehicle is out of a threshold range.

15. The method of claim 13, wherein the obtaining of the second SOH includes:
determining, by the controller, reliability for the first SOH based on a degree to which the first SOH of the battery provided in the target vehicle deviates from a threshold range; and
obtaining, by the controller, the second SOH of the battery provided in the target vehicle from the BMS in response that the reliability does not exceed a threshold.

16. The method of claim 15, wherein the correcting of the first SOH further includes determining, by the controller, a reflection rate of the second SOH based on the determined reliability.

17. A system for predicting a state of health (SOH) of a battery, the system comprising:
a server configured to train a SOH prediction model using a training dataset including battery information of a battery in a probe vehicle, driving information of the probe vehicle, and a SOH of the battery in the probe vehicle; and
a SOH prediction apparatus including a controller configured to predict a first SOH of a battery provided in a target vehicle based on the SOH prediction model,
wherein the controller of the SOH prediction apparatus is configured to predict the first SOH by use of at least one of a speed and an accumulated mileage of the target vehicle, and a voltage, a current, a temperature, and a number of charging times of the battery in the target vehicle.

18. The system of claim 17, wherein the battery information includes at least one of a voltage, a current, a temperature, a number of fast charging, a number of slow charging, or a combination thereof in the battery of the probe vehicle.

19. The system of claim 17, wherein the driving information includes at least one of a vehicle speed, an accumulated mileage, a driving time, or a combination thereof in the probe vehicle.

20. The system of claim 17, wherein the controller is further configured to obtain a second SOH of the battery provided in the target vehicle from a battery management system (BMS) through a vehicle network, and correct the first SOH by use of the second SOH.
